(19) United States
(12) Patent Application Publication
(10) Pub. No.: US 2025/0246390 A1
(43) Pub. Date: Jul. 31, 2025

(54) SEALING ARTICLES FOR PLASMA RESISTANCE APPLICATIONS

(71) Applicant: Taiwan Semiconductor Manufacturing Company, LTD., Hsinchu (TW)

(72) Inventors: Chung-Ming Huang, Tainan (TW); Ren-Guan Duan, Fremont, CA (US); Chiun-Da Shiue, Hsinchu (TW); Chin-Han Meng, Hsinchu (TW)

(21) Appl. No.: 18/424,455

(22) Filed: Jan. 26, 2024

(51) Int. Cl. H01J 9/26; H01J 37/32

(52) U.S. Cl. CPC H01J 9/266; H01J 37/32467; H01J 37/32513; H01J 2209/264; H01J 2237/166

(57) ABSTRACT

A fluoroelastomer is formed by polymerizing a reaction mixture that comprises vinyl-functionalized silica cages, tetrafluoroethylene, a perfluoroalkyl vinyl ether, a curative, and a polymerization initiator. The fluoroelastomer has excellent chemical resistance and thermal resistance, and is suitable for use in plasma treatment systems in sealing applications. The fluoroelastomer has reduced particle formation as erosion occurs over time.

### BACKGROUND

Integrated circuits are formed on a semiconductor wafer. Photolithographic patterning processes use ultraviolet light to transfer a desired mask pattern to a photoresist on a semiconductor wafer. Etching processes may then be used to transfer to the pattern to a layer below the photoresist. This process is repeated multiple times with different patterns to build different layers on the wafer substrate and make a useful device. Plasma treatment is used for various applications in the integrated circuit production process, such as cleaning the wafer or for etching.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a representative illustration of a three-dimensional fluoroelastomer matrix with covalently bonded silica cages, in accordance with some embodiments.

FIG. 2A is a plan view of a sealing ring, such as an O-ring.

FIG. 2B is a cross-sectional view of an O-ring having a circular cross-section.

FIG. 2C is a cross-sectional view of an O-ring having a rectangular cross-section.

FIG. 2D is a cross-sectional view of a T-ring with the stem of the T on the outer perimeter.

FIG. 2E is a cross-sectional view of a T-ring with the stem of the T on the inner perimeter.

FIG. 2F is a cross-sectional view of an X-ring.

FIG. 3 is a flowchart illustrating a first method for forming a sealing article, such as an O-ring.

FIG. 4 is a side view of a plasma treatment system that incorporates sealing articles, in accordance with some embodiments of the present disclosure.

FIG. 5 is a flowchart illustrating a plasma etching method, in accordance with some embodiments.

FIG. 6 is a side cross-sectional view illustrating the plasma treatment system in use in a plasma etching process.

FIG. 7 is a side cross-sectional view showing the plasma treatment system of FIG. 6 performing plasma treatment on a wafer substrate.

FIG. 8 is a side cross-sectional view showing the plasma treatment system of FIG. 6 after plasma treatment, with loading pin cushions contacting the wafer substrate to dissipate residual charge.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Numerical values in the specification and claims of this application should be understood to include numerical values which are the same when reduced to the same number of significant figures and numerical values which differ from the stated value by less than the experimental error of conventional measurement technique of the type described in the present application to determine the value. All ranges disclosed herein are inclusive of the recited endpoint.

The term “about” can be used to include any numerical value that can vary without changing the basic function of that value. When used with a range, “about” also discloses the range defined by the absolute values of the two endpoints, e.g. “about 2 to about 4” also discloses the range “from 2 to 4.” The term “about” may refer to plus or minus 10% of the indicated number.

The term “vinyl” refers to a structure of the formula —CX═CX₂, where each X is hydrogen or fluorine.

The term “ether” refers to a structure of the formula —O—, where the oxygen atom is bonded to two different carbon atoms.

The term “alkyl” refers to a structure composed entirely of carbon atoms and hydrogen atoms which is fully saturated (i.e. does not contain double or triple bonds). The alkyl structure may be linear, branched, or cyclic. The alkyl structure may bond to one or two other atoms, depending on the context in which it is used. For example, both methyl (—CH₃) and methylene (—CH₂—) should be considered alkyl structures. As used herein, an alkyl structure contains 1 to 8 carbon atoms. An alkyl structure may be substituted.

The term “aryl” refers to an aromatic structure composed entirely of carbon atoms, and optionally hydrogen atoms along the perimeter of the structure. As used herein, an aryl group has from 6 to about 18 carbon atoms. The term “aryl” should not be construed as including substituted aromatic structures, such as methylphenyl group (7 carbon atoms). The aromatic structure may bond to one or two other atoms, depending on the context in which it is used. For example, both phenyl (—C₆H₅) and phenylene (—C₆H₄—) should be considered aromatic structures. An aryl structure may be substituted.

As used herein, the term “copolymer” refers to a polymeric molecule derived from two or more monomers, as opposed to a homopolymer, which is a molecule derived from only one monomer.

The term “monomer” refers to a molecule that can react with other monomers to form a polymer. A “repeating unit” is derived from a monomer, and they differ in a known manner in their structure. These two terms may be used interchangeably.

The term “up to X” is used in this disclosure to indicate an amount of a given material. This term should be construed to require the given material to be present in an amount greater than zero, or in other words to exclude the value zero.

The present disclosure relates to fluoroelastomers, methods for making such fluoroelastomers, compositions containing fluoroelastomers, and articles made from such fluoroelastomers and their use in various devices used in semiconductor manufacturing processes. Plasma treatment systems are used in such processes, and generate high-energy plasma for various applications. Sealing articles, such as sealing rings, are used to isolate the plasma within a processing chamber, as well as to maintain vacuum or pressure, keep chemicals within the chamber, and prevent external impurities from entering the chamber. The sealing rings themselves must have high chemical and thermal resistance. Fluorine-containing elastomers exhibit high chemical resistance, plasma resistance, and thermal resistance.

In the present disclosure, improvements are made to fluoroelastomers. Vinyl-functionalized silica cages are added to the reaction mixture during the fluoroelastomer polymerization process. As a result, the silica cages can become part of the fluoroelastomer backbone in a given polymer strand, or can be pendant groups, or can act as a crosslinking agent between polymer strands to create a three-dimensional matrix or network structure.

Silica cages can be synthesized by conventional methods. For example, in sol-gel synthesis, silicon alkoxides or inorganic silicon salts are hydrolyzed and condensed in the presence of a catalyst. Suitable examples of silicon-containing precursors may include silicon alkoxides, particularly silicon tetraalkylorthosilicates such as silicon tetramethylorthosilicate (TMOS) or silicon tetraethylorthosilicate (TEOS); silicon salts like sodium silicate; and silanes such as dimethoxydimethylsilane or chlorodimethylsilane. If desired, functionalized silicon-containing precursors may also be included, such as hexyltrimethoxysilane or phenyltrimethoxysilane (alkyl or aryl groups); 3-glycidoxypropyltrimethoxysilane (epoxy group); or N-phenyl-3-aminopropyltrimethoxysilane. Catalysts may include acids or bases such as triethylamine. In other methods, silica cages are formed around surfactant micelles such as cetyltrimethylammonium bromide (CTAB).

The resulting silica cages are three-dimensional structures. They may be complete cages (resembling a polygon) or they may be open cages (resembling a polygon in which one or more vertices are missing). Silsesquioxanes are one example of silica cages. In some particular embodiments, the molar ratio of silicon to oxygen in silica cages may range from about 1:1 to about 1:3. The cages may be considered to have pores or holes whose size may vary, for example ranging from about 4 nanometers to about 12 nanometers.

Vinyl-functionalized silica cages can be synthesized in at least two ways. First, a vinyl-functionalized silane may be included during the hydrolysis/condensation process. Second, a vinyl-functionalized silane can be grafted to a silica cage. In this regard, silica cages usually have reactive groups on their surface, such as hydroxyl groups, which can react with the vinyl-functionalized silane. Grafting modifies the surface of the silica cages to include vinyl groups. Non-limiting examples of vinyl-functionalized silanes which can be used in either of these synthesis methods can include vinyltrimethoxysilane, vinyltriethoxysilane, or allyl (chloro) dimethylsilane; and acrylated silanes such as 3-methacroyloxypropyltrimethoxysilane. In some more specific embodiments, the vinyl groups are perfluorovinyl groups, i.e. the hydrogen atoms have been replaced with fluorine atoms as well. The number of vinyl groups on a silica cage can be adjusted by controlling the molar ratio of vinyl-functionalized silanes to the other silanes or by varying their time of addition during hydrolysis/condensation, or by controlling the molar ratio of vinyl-functionalized silane to silica cages during grafting. As a result, vinyl-functionalized cages may have one, two, three, or more vinyl groups on their surface.

Continuing, in particular embodiments, the fluoroelastomers of the present disclosure are perfluoroelastomers (FFKM) as defined by ASTM D1418. Perfluoroelastomers are copolymers that are usually derived from monomers that include tetrafluoroethylene (TFE) and perfluoroalkyl vinyl ethers (PAVE). Examples of PAVEs include perfluoromethyl vinyl ether and perfluoroethyl vinyl ether.

Perfluoroelastomers usually include a cure site monomer (CSM), which provides a reactive site in the elastomer which can then react to form a three-dimensional matrix or network. However, in the present disclosure the vinyl-functionalized silica cages can serve this role, and so traditional CSMs do not need to be present. However, if desired, CSMs such as a cyano-functional vinyl ether or another CSM containing other functional groups such as nitrile, carboxyl, halogen, or alkoxycarbonyl may be used as well.

Perfluoroelastomers can be cured using a curative, or crosslinking agent, to aid in the formation of a three-dimensional matrix or network. Some non-limiting examples of suitable curatives include triallyl isocyanurate (TAIC); 2,2-bis [3-amino-4-hydroxyphenyl] hexafluoropropane, also known as diaminobisphenol AF or BOAP; phosphonium salts such as fluoroarylalkyl phosphonium salts; tetraphenyl tin; and ammonia.

Perfluoroelastomers may be prepared using any suitable polymerization process. Examples of such processes may include radical polymerization or emulsion polymerization. Polymerization initiators may include organic or inorganic peroxides, azo compounds, persulfates, percarbonates, peresters, and the like.

The fluoroelastomers of the present disclosure are formed from a reaction mixture that comprises vinyl-functionalized silica cages, tetrafluoroethylene (TFE), a perfluoroalkyl vinyl ether (PAVE), a curative and a polymerization initiator. The reaction mixture may also include at least one filler, which can improve desirable properties such as compression set, chemical resistance, plasma resistance, or other mechanical properties. Examples of such fillers may include polytetrafluoroethylene (PTFE); silicon dioxide (SiO₂); and perfluoroalkoxy plastics (PFA). Fillers are usually provided in the form of particles or fibers which become crosslinked with the fluoroelastomers as well. In some particular embodiments, two fillers (a first filler and a second filler) are used.

For purposes of the present disclosure, with respect to the term “parts per hundred rubber” or “phr”, only the tetrafluoroethylene (TFE) and the perfluoroalkyl vinyl ether (PAVE) are considered to form the rubber. PHR is also used as a measure of weight in the present disclosure, and not mole percent or volume percent.

In some particular embodiments, the vinyl-functionalized silica cages may comprise up to 10 phr of the reaction mixture. This amount can be adjusted to provide a desired amount of incorporation into the fluoroelastomer. In some particular embodiments, the curative may comprise up to 5 phr of the reaction mixture. When one or more fillers are present, the filler(s) may comprise up to 20 phr of the reaction mixture. Combinations of these amounts are contemplated. Other ranges and values are also within the scope of this disclosure.

In some embodiments, the molar ratio of the TFE to the PAVE in the fluoroelastomer may range from about 5:95 to about 95:5, including from about 15:85 to about 85:15, or from about 30:70 to about 70:30, or from about 40:60 to about 60:40. In some other embodiments, the molar ratio of TFE to PAVE is from about 5:95 to about 65:35, or from about 65:5 to about 95:5. Other combinations of ranges with these values are also contemplated, and other ranges and values are also within the scope of this disclosure.

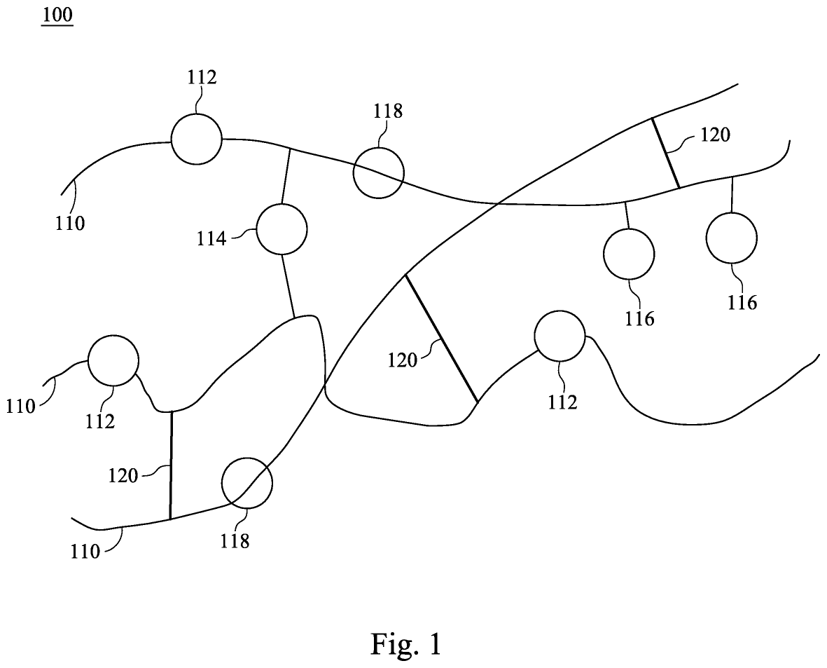

The polymerization of the various components in the reaction mixture is performed at conventional temperatures, times, and pressures, as is the subsequent curing thereof. The resulting fluoroelastomer is representatively illustrated in FIG. 1. The fluoroelastomer 100 forms a three-dimensional matrix due to crosslinking between different polymer strands. Here, three polymer strands 110 are illustrated. The silica cages are illustrated as circles. In this regard, the silica cages may form a part of the backbone of a polymer strand as illustrated by circles 112. This can result, for example, when a vinyl-functionalized silica cage has two vinyl groups that are polymerized into a single polymer strand. Alternatively, a silica cage with two vinyl groups may also act as a cross-linker between two polymer strands, as illustrated by circles 114. A silica cage with only one vinyl group may be a pendant group or sidechain of a polymer strand, as illustrated with circles 116. It is also possible for a polymer strand to pass through the pores of a silica cage, as illustrated by circles 118. Other crosslinks 120 may also be formed as the result of additional curative present in the reaction mixture.

Each polymer strand backbone may have the general formula of Formula (I):

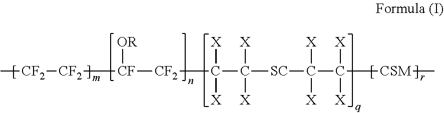

where m is the molar ratio of the TFE, n is the molar ratio of the PAVE, q is the molar ratio of the silica cage (SC) which is incorporated into the backbone, and r is the molar ratio of any cure site monomer, and wherein 0.05≤m, n≤0.95 and 0≤q, r≤0.10, and m+n+q+r=1 and
R is alkyl having 1 to about 4 carbon atoms; and
each X is independently hydrogen or fluorine.

It should be noted that Formula (I) does not illustrate silica cages which are present as pendant groups, or silica cages that act as crosslinkers, and also does not illustrate crosslinks between polymer strands.

The fluoroelastomer may be compounded with other additives to form a polymeric composition. Examples of such additives may include cure accelerators, co-curatives, co-agents, processing aids, plasticizers, fillers, and other modifiers. Additional examples of additives may include silica, carbon black, clay, talc, metallic fillers such as aluminum oxide (Al₂O₃), metal carbides, metal nitrides, colorants, organic dyes and/or pigments, and the like.

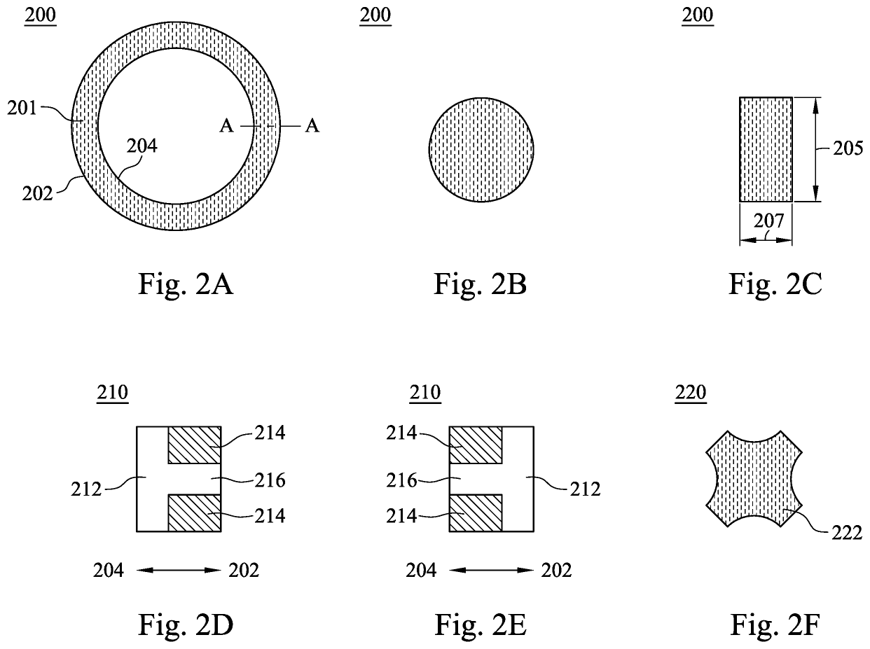

The polymeric compositions can be formed into a molded article by placing the polymeric composition into a mold and applying heat and pressure within the mold, for example by compression molding, to make an article having the desired shape. The polymeric composition can be put into the mold as a gum or paste, or placed into the mold as a rubber and then cured. In particular embodiments, the article formed from compositions containing the perfluoroelastomers of the present disclosure is a sealing article such as an O-ring, which can be used in plasma treatment systems due to the improved chemical resistance and thermal resistance. Other articles may include T-rings, X-rings, or rings of other cross-sectional shapes. FIG. 2A is a plan view of an O-ring 200. As seen here, the O-ring is a solid body 201 having an annular shape. The O-ring has an outer perimeter 202 and an inner perimeter 204.

FIG. 2B and FIG. 2C are cross-sectional views of different embodiments of the O-ring through line A-A of FIG. 2A. In the embodiment of FIG. 2B, the O-ring has a circular cross-section. In the embodiment of FIG. 2C, the O-ring has a rectangular cross-section. The height 205 and width 207 of the O-ring may vary as needed for a given application. Other cross-sectional shapes may also be used, such as an elliptical cross-section.

FIG. 2D and FIG. 2E are cross-sectional views of a T-ring 210. A T-ring has the same plan view shown in FIG. 2A. The fluoroelastomer 212 has a T-shaped cross-section. In addition, two backup rings 214 are present on each side of the stem 216 of the T-shape. T-rings may be useful in applications with a wide range of pressures while maintaining high seal efficiency. In FIG. 2D, the stem is on the outer perimeter 202, and in FIG. 2E, the stem is on the inner perimeter 204.

FIG. 2F is a cross-sectional view of an X-ring 220. The X-ring may be described as having four lobes 222, and can increase the amount of sealing surface available for use.

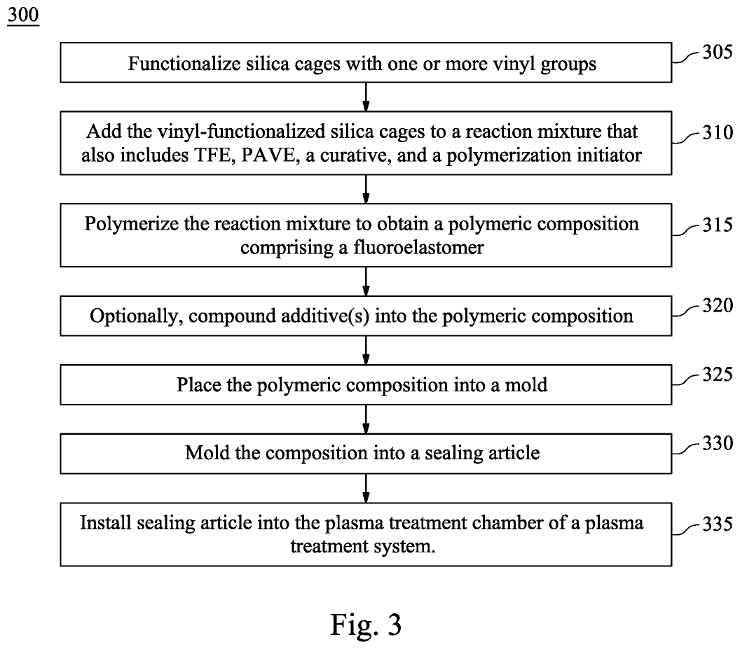

Summarizing, then, FIG. 3 is a flowchart illustrating a first method 300 for forming a sealing article, such as an O-ring, from the fluoroelastomers of the present disclosure, in accordance with some embodiments. In step 305, silica cages are functionalized with one or more vinyl groups. As explained above, this can be done during silica cage synthesis, or by grafting of already-synthesized silica cages. In step 310, the vinyl-functionalized silica cages are added to a reaction mixture that also includes TFE, PAVE, a curative, and a polymerization initiator. In step 315, the reaction mixture is polymerized to obtain a polymeric composition comprising a fluoroelastomer. The fluoroelastomer may be in the form of a matrix formed from fluoroelastomer strands. In optional step 320, additives may be compounded into the polymer matrix of the polymeric composition. In step 325, the polymeric composition is placed into a mold. In step 330, the composition is molded into a sealing article, such as an O-ring. This may be performed, for example, by the application of suitable pressure and heat. Going further, in step 335, the sealing article is installed into the plasma treatment chamber of a plasma treatment system. This may be done, for example, by installing the sealing article into a groove. The groove is usually located either within the housing of the chamber, or on a component that is installed or connected to the housing or within the chamber itself.

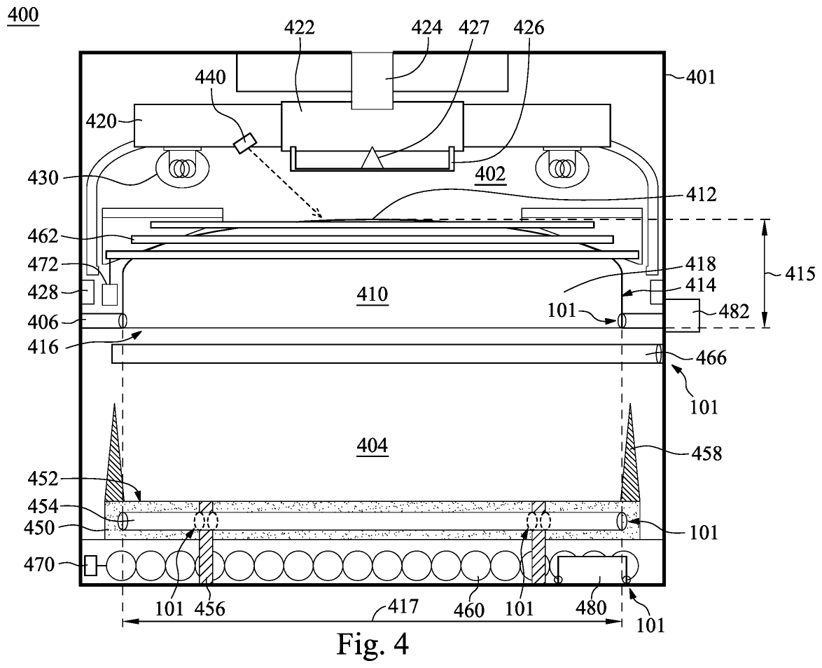

The sealing rings made from fluoroelastomers of the present disclosure may be used in plasma treatment systems, such as those used for plasma etching. FIG. 4 is a side cross-sectional schematic diagram of an example plasma treatment system 400 in accordance with some embodiments of the present disclosure. The system may be suitable for application such as high density plasma chemical vapor deposition (HDPCVD), plasma-enhanced CVD (PECVD), or atomic layer deposition (ALD).

The system includes a housing 401 that contains a cooling chamber 402 and a plasma treatment chamber 404. The cooling chamber is located over or above the plasma treatment chamber. The system also includes a dome 410 located between the cooling chamber 402 and the plasma treatment chamber 404.

The cooling chamber 402 and the plasma treatment chamber 404 are isolated from each other. In other words, there is no exchange of gas, liquid, or other materials between the cooling chamber 402 and the plasma treatment chamber 404. This isolation is done structurally, and in FIG. 4 is done by the dome 410 and an annular horizontal wall 406 surrounding the dome.

Referring first to the dome 410, the dome is made of a material that is configured to transmit RF energy, or in other words the dome is generally transparent to RF. An RF induction field is typically transmitted by an inductor antenna within the cooling chamber and through the dome. Thus, the dome desirably has a low impedance to the RF induction field of the inductor antenna or has an electric field susceptibility sufficiently low to transmit the induction field through the dome with minimal power loss. A suitable composition for the dome has high transmittance (i.e., low loss tangent) across RF frequencies. If RF transmittance is low, energy may undesirably be absorbed and converted into excessive heat. Such heat may both degrade the plasma treatment process due to lost RF energy while also causing excessive heating of components and the creation of thermal gradients. The dome material should also resist erosion from the plasma treatment environment.

In some embodiments, the dome is made of a ceramic material. Non-limiting examples of ceramic materials that can be used to make the dome 410 include silicon, silicon dioxide (SIO₂), silicon carbide, alumina (Al₂O₃), germanium, Group III-V compound semiconductors such as gallium arsenide and indium phosphide, and Group II-II-V compound semiconductors such as mercury cadmium-telluride. In some specific embodiments, the dome is made from silicon dioxide (SiO₂) or alumina (Al₂O₃).

During the plasma treatment process, the dome 410 may capture byproducts and polymer etchant particles generated in the plasma treatment chamber 404. Such byproducts may come, for example, from the photoresist on a wafer substrate that is being etched, or from the metal films being etched, or the etchant gases. When these byproducts and other particles adhere to the dome, they do not land on the wafer substrate. Thus, the dome aids in keeping the plasma treatment chamber cleaner and/or preventing the byproducts/particles from re-depositing onto the wafer.

In some embodiments and as illustrated in FIG. 4, the dome 410 may include a top portion 412 that correspond in shape to a portion of a sphere cut off by a plane (i.e. a spherical dome), and may be hemispherical. The dome may also include a circumferential sidewall 414 that extends downward from the top portion 412. The overall dome 410 has a height 415 and a diameter 417. The dome may also be described as having a first surface 416 facing the wafer substrate or within the plasma treatment chamber 404, and having a second surface 418 facing away from the wafer substrate or within the cooling chamber 402.

The top of the cooling chamber 402 is defined by an annular insulating cover 420 which surrounds a cooling pipe 422. A cooling gas is fed into the cooling chamber through a cooling gas inlet 424 and through the cooling pipe 422. A diffuser 426 is attached to the insulating cover 420 which includes a cone 427 which faces the gas inlet 424.

One or more heat sources 430 (illustrated here as bulbs) may also be present within the cooling chamber 402 to generate heat for controlling the dome temperature within a set temperature range. A temperature sensor 440 (e.g. an infrared sensor) is configured to measure the temperature of the dome surface. An upper electrode or RF coil 462 may be located above the dome 410 within the cooling chamber 402. This electrode/coil is used during plasma generation.

One or more cooling gas outlets 428 are also present in the cooling chamber. In use, cooling gas passes from the cooling gas inlet 424 through the diffuser 426 towards the dome 410. The cooling gas may flow across the entire surface of the dome and exit through the cooling gas outlets 428, which are illustrated here as being near the horizontal wall 406.

Referring now to the plasma treatment chamber 404, a wafer support pedestal 450 is present within the housing. The pedestal may be configured to hold a semiconductor wafer substrate (not shown) in a desired position. The pedestal 450 includes a support surface 452 which contacts the wafer substrate. The support surface itself is usually made of an electrically insulating material.

In particular embodiments, the pedestal is in the form of an electrostatic chuck that uses an electrostatic holding force to secure the wafer substrate. As illustrated here, the pedestal includes a chuck electrode 454 located below the support surface 452. Extending through the chuck electrode and the support surface are loading pins 456, which can be used to raise and lower the wafer substrate. In some embodiments, channels may be provided on the back side of the electrostatic chuck for providing gases or fluids to cool the wafer substrate during plasma treatment. In this way, warpage and/or other damage to the wafer substrate may be reduced or minimized.

Alternatively, the pedestal may apply vacuum pressure to hold the wafer substrate in place by suction. As yet another alternative, the pedestal may interact mechanically, for example using clamps or retaining rings or the like, to hold the wafer substrate in place using a mechanical holding force.

A focus ring 458 is also present around the wafer support surface 452. The focus ring is designed to improve etch uniformity around the wafer edge or perimeter, by permitting the plasma to extend beyond the wafer perimeter and focusing the electric field within the focus ring. The focus ring is typically made of an insulating material, e.g. quartz, and is a consumable part that is periodically replaced.

Continuing, a lower electrode 460 is located below the wafer support surface 452, and an upper electrode 462 is located above the wafer support pedestal 450. The dome 410 is also located above the wafer support pedestal 450. The dome 410 is located between the wafer support pedestal 450 and the upper electrode 462, and physically separates the upper electrode 462 from the interior of the plasma treatment chamber 404. Similarly, the lower electrode 460 may also be isolated from the interior of the reaction chamber. The electrodes may be, for example, in the shape of a planar coil. The electrodes are used to provide energy for ionizing gas molecules so as to generate a plasma.

The system also includes a gas inlet 466, through which process gases are introduced into the plasma treatment chamber. It should be understood that these process gases are different from the cooling gas described above which does not enter the plasma treatment chamber. The gas inlet may be in the form of, for example, a showerhead and/or gas lines for supplying the process gases. The showerhead and/or gas lines are connected to gas sources (not shown) for providing the specified gas. One or more gas outlets 480 is also present for removing undesired gases, and for reducing the pressure within the plasma treatment chamber. A gas outlet can be connected to a pump (not shown) for creating vacuum. A door (not shown) is also present for accessing the plasma treatment chamber, to insert and remove the wafer substrate.

Radiofrequency (RF) generators are present for applying RF power. A lower RF generator 470 is coupled to the lower electrode 460, and an upper RF generator 472 is coupled to the upper electrode 462.

A controller 482 is used to control the various inputs and outputs, and to measure various conditions within the housing for both the cooling process and the plasma treatment process. The system may also include sensors (not shown) for monitoring applicable parameters. For example, such sensors may include those for tracking the flow rate of various gases, for measuring the content of gases exiting the plasma treatment chamber, for measuring the pressure within the plasma treatment chamber, the temperature of the wafer substrate, the temperature of the cooling gas, the temperature of the dome (i.e. sensor 440), etc. The controller can also determine whether to activate or deactivate the system, how to vary the voltage to the electrodes, how to vary the gas mixture, how fast/strongly the cooling gas should flow into the cooling chamber, and potentially also control the motion of any automated handling system that may be present, etc. It is noted that these various parameters may not have to be held steady during operation, and could be changed by the controller operating a computer program which alters their setpoints as appropriate. The controller may also include a user interface for communicating with operators. If desired, different controllers may be used for controlling the cooling chamber and the plasma treatment chamber.

The controller may be implemented on one or more general purpose computers, special purpose computer(s), a programmed microprocessor or microcontroller and peripheral integrated circuit elements, an ASIC or other integrated circuit, a digital signal processor, a hardwired electronic or logic circuit such as a discrete element circuit, a programmable logic device such as a PLD, PLA, FPGA, Graphical card CPU (GPU), or PAL, or the like. Such devices typically include at least memory for storing a control program (e.g. RAM, ROM, EPROM) and a processor for implementing the control program.

The various components of the plasma treatment system may be made using materials and processes known in the art. Examples of suitable materials can include metals, plastics, etc. Common enhancements may also be used. For example, the various surfaces within the plasma treatment chamber may include a protective coating.

Sealing articles, such as O-rings, made from the polymeric compositions containing a perfluoroelastomer may be present in several different locations in the plasma treatment chamber 404. Generally, the system is constructed by joining smaller components, and O-rings can be installed at any of those junction points within the plasma treatment system that may be exposed to plasma. For example, referring to FIG. 4, sealing articles 101 may be present at the junction between the dome 410 and the annular horizontal wall 406 surrounding the dome; or around the chuck electrode 454; or at the interface between the support surface 452 and/or the chuck electrode 454 and the loading pins 456 (in dashed lines); or at the junction between the housing 401 and either the gas inlet 466 or the gas outlet 480; or at any junction between the housing 401 and any sensors that are plugged in for monitoring the plasma treatment chamber 404.

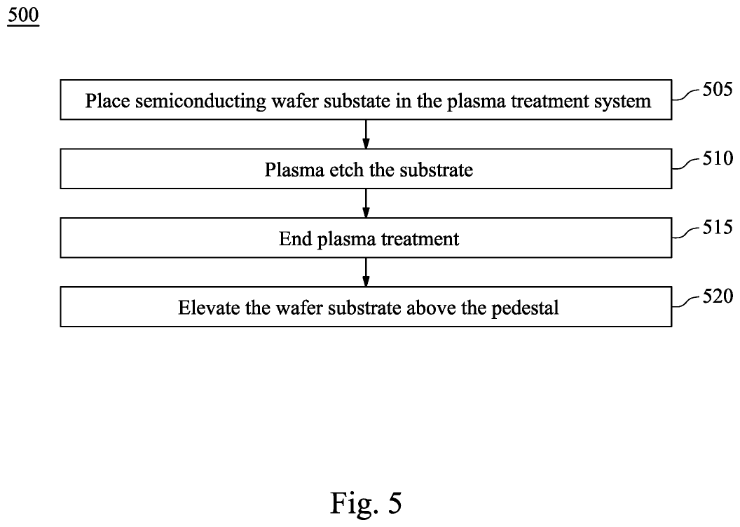

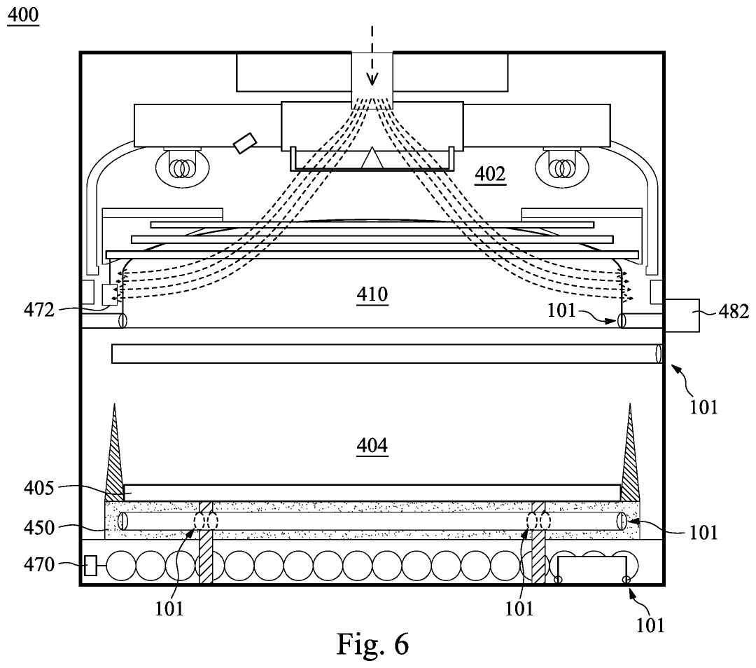

FIG. 5 is a flowchart illustrating a method 500 for plasma etching using the plasma treatment system, according to some embodiments of the present disclosure. Some of the method steps are illustrated in FIGS. 6-8.

In step 505, a semiconducting wafer substrate 405 is placed in the plasma treatment system 400. As illustrated in FIG. 6, the wafer substrate 405 is placed on the wafer support pedestal 450. As indicated here as well, the flow of cooling gas into the cooling chamber 402 can be started for cooling the dome 410.

When used for production, the wafer substrate itself can be a wafer made of any semiconducting material. Such materials can include silicon, for example in the form of crystalline Si or polycrystalline Si. In alternative embodiments, the substrate can be made of other elementary semiconductors such as germanium, or may include a compound semiconductor such as silicon carbide (SIC), gallium arsenide (GaAs), indium arsenide (InAs), and indium phosphide (InP).

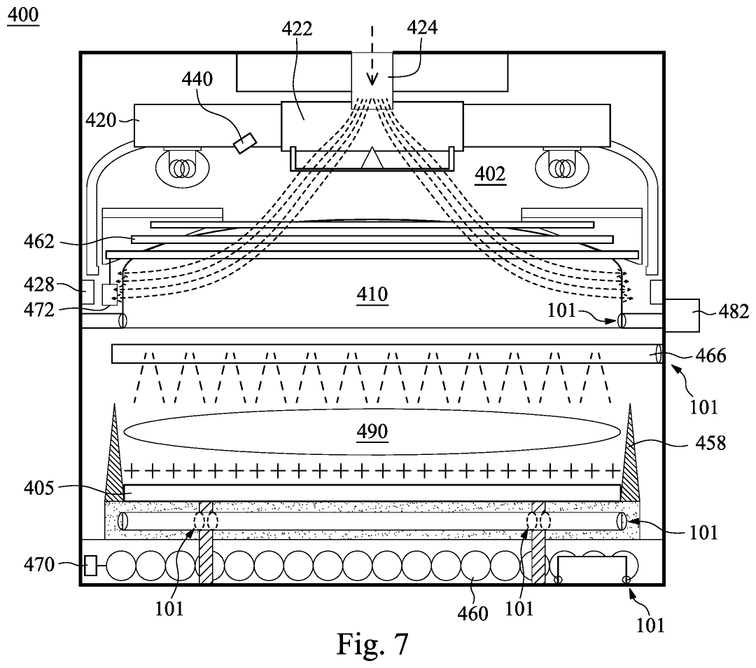

Next, in step 510, the wafer substrate is plasma etched. As illustrated in FIG. 7, plasma treatment is performed upon the wafer substrate 405. The plasma treatment can be performed, for example, as part of a dielectric barrier discharge (DBD) process, a reactive ion etching (RIE) process, or a sequential plasma (SPAB) process. Voltage provided by the RF generators 470, 472 is applied between the upper electrode 460 and the lower electrode 462 to ignite and sustain a plasma 490, which is focused above the wafer substrate by the focus ring 458. The radiofrequency is usually operated at 13.56 megahertz (MHZ), although other frequencies such as 2 MHz or 60 MHz may be used, depending on the application. The power used to generate the plasma may range from about 10 watts (W) to about 2,000 W. Once ignited, the plasma can be sustained by electric currents produced by electromagnetic induction associated with time-varying magnetic fields, or can become self-sustaining.

In some embodiments, the plasma treatment is performed in a vacuum environment, for example with the pressure within the housing being from about 0.1 pascals (Pa) to about 100 Pa. However, the pressure may be higher and could simply be sub-atmospheric, for example a pressure of about 10 kPa to about 95 kPa (for comparison, atmospheric pressure is about 101 kPa).

The process gas used for generating the plasma may include one or more gases that enter through the showerhead 466. Depending on the application, for example, the process gases may include nitrogen (N₂), hydrogen (H₂), argon (Ar), helium (H₂), fluorine (F₂), chlorine (Cl₂), oxygen (O₂), hydrogen bromide (HBr), hydrofluoric acid (HF), nitrogen trifluoride (NF₃), or sulfur hexafluoride (SF₆), or hydrofluorocarbons of the general formula CₓH_{y}F_{z}. Due to the plasma treatment, a residual voltage may remain on the wafer substrate, indicated here as a positive charge on the wafer substrate 405. The sealing articles of the present disclosure have high resistance and are less affected by the plasma relative to conventional sealing articles.

During the plasma treatment process, cooling gas is flowing through the cooling gas inlet 424, the cooling pipe 422, and the diffuser 200 (as indicated by arrows) into the cooling chamber 402. The cooling gas is blown or directed towards the dome 410. In some embodiments, the cooling gas is compressed dry air (CDA). The cooling gas directed through the diffuser towards the dome may enter through the gas inlet at a temperature in the range of about 20° C. to about 25° C. The cooling gas flows over the dome and out the gas outlets 428. The temperature in the plasma treatment chamber 404 just above the substrate may be in the range of about 70° C. to about 80° C. In other embodiments, the temperature may be elevated, for example up to 400° C.

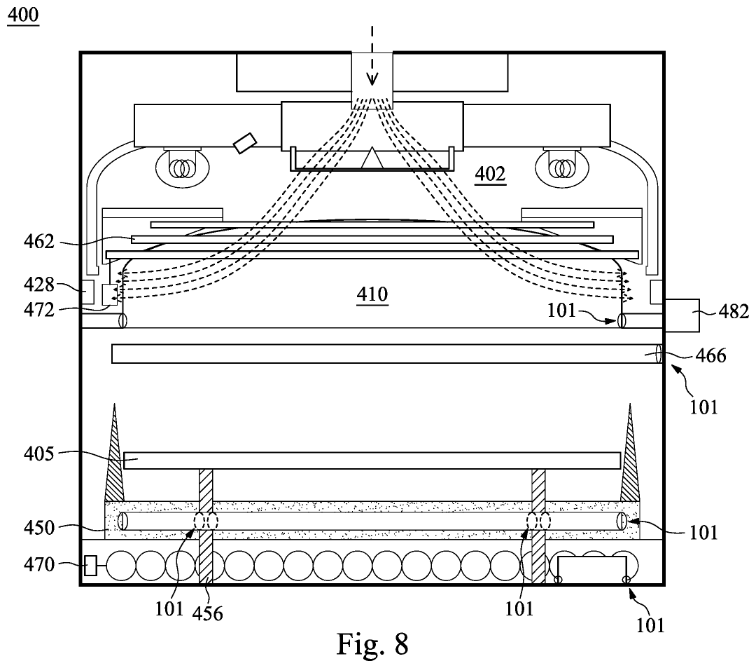

In step 515, the plasma treatment process ends. In FIG. 8, the plasma treatment is complete. In step 520, the loading pins 456 are raised to elevate the wafer substrate 405 above the pedestal 450. The loading pins now contact the bottom of the wafer substrate to dissipate any residual charge on the wafer substrate. Automated handling tools (not shown) can then grasp the wafer/semiconductor wafer substrate to a subsequent processing tool. The flow of cooling gas may continue here as well.

The plasma treatment system or tool can be used for performing dry etching. Dry etching can be used to form trenches and/or vias in a layer, and is a highly anisotropic process for obtaining high aspect ratios (i.e. predominantly vertical walls). For dry etching, for example, a patterned photoresist layer is present over a metal layer on the wafer substrate. The plasma treatment tool is then used to etch the exposed metal. Etch products may include for example, FCN, COₓ, SiClₓ, and/or SiFₓ.

In particular embodiments, the plasma treatment system/tool is used for patterning of aluminum-copper (AlCu) alloy thin films. AlCu alloy is widely used as a very large-scale integration (VLSI) interconnection metal for semiconductor devices due to its high conductivity, good ductility, and good adhesion to the underlying substrate. The patterning of AlCu is commonly done using reactive ion etching (RIE). Suitable etchant gases contain chlorine, such as BCl₃, Cl₂, CCl₄, and SiCl₄. Other gases can be added for anisotropic etching, such as ChCl₃, N₂, CHF₃, and C₂H₄.

The plasma treatment system can also be used for cleaning. The plasma treatment can remove contaminants from the surface of a wafer substrate. In addition, the surface is made hydrophilic by increasing the number of-OH groups on the surface, which may be beneficial for forming strong fusion bonds when wafer-to-wafer bonding is desired.

Use of the fluoroelastomers of the present disclosure for making sealing articles in plasma treatment systems offers several advantages. As the fluoroelastomer erodes over time, the silica cages will not become a particle source that can cause contamination on the wafer substrate being processed in the treatment system, because they are covalently bonded into the polymer matrix. The silica cages are well dispersed and homogeneously distributed through the polymer matrix. The sealing rings also have improved plasma resistance and compression recovery.

In this regard, the “compression set” measures the ability of an elastomeric material to be compressed and return to its original shape. The compression set value is expressed as the amount of permanent deformation that occurs. For example, a compression set value of 0% would mean that the material returns to its original shape, whereas a compression set value of 100% would mean the material did not recover at all. Lower values are more desirable. In the present disclosure, compression set was measured by loading the article to obtain an initial deformation of 25% of the height of the article at 200° C. for 72 hours, and recovery was measured 30 minutes after removing the load. A compression set value of less than 20% is generally desired.

The present disclosure thus relates in various embodiments to methods for forming a sealing article. A polymeric composition is placed into a mold. Heat and pressure are applied to make the sealing article. The polymeric composition comprises a fluoroelastomer comprising monomers derived from vinyl-functionalized silica cages, tetrafluoroethylene, and a perfluoroalkyl vinyl ether.

Also disclosed in various embodiments are methods for using a sealing article, comprising installing the sealing article within a plasma treatment chamber. The sealing article comprises a fluoroelastomer comprising monomers derived from vinyl-functionalized silica cages, tetrafluoroethylene, and a perfluoroalkyl vinyl ether.

Also disclosed in various embodiments are plasma treatment systems comprising a plasma treatment chamber. A sealing article is present within the plasma treatment chamber. The sealing article comprises a fluoroelastomer comprising monomers derived from vinyl-functionalized silica cages, tetrafluoroethylene, and a perfluoroalkyl vinyl ether.

Also disclosed in various embodiments are articles formed from a polymeric composition that comprises a fluoroelastomer. The fluoroelastomer is formed by polymerizing a reaction mixture that comprises vinyl-functionalized silica cages, tetrafluoroethylene, a perfluoroalkyl vinyl ether, a curative, and a polymerization initiator.

Also disclosed in various embodiments are polymeric compositions comprising a fluoroelastomer containing silica cages. The fluoroelastomer is formed by polymerizing a reaction mixture that comprises vinyl-functionalized silica cages, tetrafluoroethylene, a perfluoroalkyl vinyl ether, a curative, and a polymerization initiator.

Other embodiments disclosed herein include fluoroelastomers comprising monomers derived from vinyl-functionalized silica cages, tetrafluoroethylene, and a perfluoroalkyl vinyl ether. The vinyl-functionalized silica cages may comprise up to 10 mole % of the fluoroelastomer. The tetrafluoroethylene may comprise about 5 to about 95 mole % of the fluoroelastomer. The perfluoroalkyl vinyl ether may comprise about 5 to about 95 mole % of the fluoroelastomer.

The present disclosure also relates in various embodiments to methods for making a fluoroelastomer containing silica cages. The fluoroelastomer is formed by polymerizing a reaction mixture that comprises vinyl-functionalized silica cages, tetrafluoroethylene, a perfluoroalkyl vinyl ether, a curative, and a polymerization initiator.

The methods, polymers, systems, and devices of the present disclosure are further illustrated in the following non-limiting working examples, it being understood that they are intended to be illustrative only and that the disclosure is not intended to be limited to the materials, conditions, process parameters and the like recited herein.

### EXAMPLES

Example E1 was a fluoroelastomer that contained 5 phr of vinyl-functionalized silica cages. Comparative Examples CE1-CE6 did not include silica cages, and instead used fillers and different curatives. The Examples were then exposed to three different plasmas (CF₄, O₂, and H₂) and their weight loss was measured. They were also tested for their compression set value as previously described. The results are provided in Table A below.

TABLE A

| | CE1 | E1 | CE2 | CE3 | CE4 | CE5 | CE6 |
|---|---|---|---|---|---|---|---|
| Polymer | FFKM | FFKM | FFKM | FFKM | FFKM | FFKM | FFKM |
| Silica cage | 0 | 5 phr | 0 | 0 | 0 | 0 | 0 |
| Filler | Organic | — | 10 phr | 10 phr | 10 phr | 15 phr | 25 phr |
| | | | PFA | PTFE | PTFE | PTFE | PTFE |
| | | | 1.8 phr | | | | |
| | | | SiO2 | | | | |
| Curative | — | 1.5 phr | 2.5 phr | 1.5 phr | 1.5 phr | 1.5 phr | 1.5 phr |
| | | TAIC | phos- | BOAP | TAIC | BOAP | BOAP |
| | | | phonium | | | | |
| | | | salt | | | | |
| CF₄ | 0.29 | 0.27 | 0.25 | 0.23 | 0.22 | 0.20 | 0.27 |
| | | | | holes | holes | | |
| O₂ | 0.78 | 0.33 | 0.39 | 0.59 | 0.65 | 0.51 | 0.53 |
| | | | pores | | Holes | | |
| H₂ | 0.80 | 0.38 | 0.43 | 0.78 | 0.83 | 0.64 | 0.58 |
| | | | pores | | | | |
| Compression | 18.5 | 16.0 | 16.9 | 12 | 22 | 12 | 14 |
| set value | | | | | | | |

As seen, Example E1 had the best plasma resistance for O₂ and H₂, and acceptable plasma resistance for CF₄, and had acceptable compression set value, without the need for fillers which have the potential to become particle sources after polymer erosion.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a sealing article, comprising:
placing a polymeric composition into a mold; and
applying heat and pressure to make the sealing article;
wherein the polymeric composition comprises a fluoroelastomer formed by polymerizing a reaction mixture that comprises vinyl-functionalized silica cages, tetrafluoroethylene, a perfluoroalkyl vinyl ether, a curative, and a polymerization initiator.

2. The method of claim 1, wherein the vinyl-functionalized silica cages comprise up to 10 phr of the reaction mixture.

3. The method of claim 1, wherein the curative comprises up to 5 phr of the reaction mixture.

4. The method of claim 1, wherein the curative is triallyl isocyanurate, diaminobisphenol AF, or a phosphonium salt.

5. The method of claim 1, wherein the reaction mixture further comprises at least one filler.

6. The method of claim 5, wherein the reaction mixture contains up to 20 phr of the at least one filler.

7. The method of claim 5, wherein the at least one filler comprises polytetrafluoroethylene, SiO₂, or a perfluoroalkoxy plastic.

8. The method of claim 5, wherein the at least one filler includes a first filler and a second filler.

9. The method of claim 1, wherein the vinyl-functionalized silica cages are formed by condensation of at least one vinyl-functionalized silane; or by grafting of at least one vinyl-functionalized silane to a silica cage.

10. A method for using a sealing article, comprising:
installing the sealing article within a plasma treatment chamber;
wherein the sealing article comprises a fluoroelastomer formed by polymerizing a reaction mixture that comprises vinyl-functionalized silica cages, tetrafluoroethylene, a perfluoroalkyl vinyl ether, a curative, and a polymerization initiator.

11. The method of claim 10, wherein the article is an O-ring.

12. The method of claim 10, wherein the vinyl-functionalized silica cages comprise up to 10 phr of the reaction mixture.

13. The method of claim 10, wherein the curative comprises up to 5 phr of the reaction mixture.

14. The method of claim 10, wherein the curative is triallyl isocyanurate, diaminobisphenol AF, or a phosphonium salt.

15. The method of claim 10, wherein the reaction mixture further comprises at least one filler.

16. The method of claim 15, wherein the reaction mixture contains up to 20 phr of the filler.

17. The method of claim 15, wherein the at least one filler comprises polytetrafluoroethylene, SiO₂, or a perfluoroalkoxy plastic.

18. The method of claim 15, wherein the at least one filler includes a first filler and a second filler.

19. A plasma treatment system comprising a plasma treatment chamber, and a sealing article within the plasma treatment chamber;
wherein the sealing article comprises a fluoroelastomer comprising monomers derived from vinyl-functionalized silica cages, tetrafluoroethylene, and a perfluoroalkyl vinyl ether.

20. The plasma treatment system of claim 19, wherein
the vinyl-functionalized silica cages comprise up to 10 mole % of the fluoroelastomer;
the tetrafluoroethylene comprises about 5 to about 95 mole % of the fluoroelastomer; and
the perfluoroalkyl vinyl ether comprises about 5 to about 95 mole % of the fluoroelastomer.
